(19) United States
(12) Patent Application Publication
(10) Pub. No.: US 2016/0268281 A1
(43) Pub. Date: Sep. 15, 2016

(54) SEMICONDUCTOR MEMORY DEVICE

(71) Applicant: Kabushiki Kaisha Toshiba, Minato-ku (JP)

(72) Inventor: Hiroyuki KUTSUKAKE, Yokkaichi (JP)

(73) Assignee: Kabushiki Kaisha Toshiba, Minato-ku (JP)

(21) Appl. No.: 14/748,882

(22) Filed: Jun. 24, 2015

Related U.S. Application Data
(60) Provisional application No. 62/133,118, filed on Mar. 13, 2015.

(51) Int. Cl. H01L 27/115; H01L 23/528; G11C 16/14; H01L 29/51; H01L 29/792; H01L 29/788; H01L 29/423

(52) U.S. Cl. CPC H01L 27/11568; H01L 29/788; H01L 23/528; H01L 29/42328; H01L 29/513; H01L 29/792; H01L 29/42344; H01L 27/11519; H01L 27/11521; H01L 27/11565; G11C 16/14

(57) ABSTRACT

According to one embodiment, a semiconductor memory device includes a substrate; a memory cell unit; a bit line; a first semiconductor area; a second semiconductor area; a first transistor provided on the second semiconductor area and including a first gate electrode, a first gate insulating film, a first electrode, and a second electrode; a second transistor provided on the substrate and including a second gate electrode, a second gate insulating film, a third electrode, and a fourth electrode; and a control unit. The control unit configured to be able to performing an erase operation, the erase operation including: applying a first voltage to the first semiconductor area and the bit line; applying a second voltage being equal to or lower than the first voltage; and applying a third voltage being equal to or lower than the first voltage.

### CROSS-REFERENCE TO RELATED APPLICATIONS

This application is based upon and claims the benefit of priority from U.S. Provisional Patent Application 62/133,118 field on Mar. 13, 2015; the entire contents of which are incorporated herein by reference.

### FIELD

Embodiments described herein relate generally to a semiconductor memory device.

### BACKGROUND

In a semiconductor memory device, a high voltage may be applied to a memory cell unit. Consequently, a risk of deterioration of a transistor provided in the periphery of the memory cell unit is conceivable.

### BRIEF DESCRIPTION OF THE DRAWINGS

FIG. 1 is a block diagram illustrating a configuration of the semiconductor device of a first embodiment;

FIG. 2 is a schematic perspective view of the memory cell unit of the first embodiment;

FIG. 3 is an enlarged schematic cross-sectional view of a part of a columnar portion of the first embodiment;

FIG. 4 is a schematic cross-sectional view of a periphery of a step-down unit of the first embodiment;

FIG. 5A to FIG. 5E are schematic circuit diagrams of the step-down unit of the first embodiment;

FIG. 6 is a schematic cross-sectional view of the periphery of the step-down unit of a second embodiment;

FIG. 7 is a schematic cross-sectional view of a periphery of a step-down unit of a third embodiment; and

FIG. 8A and FIG. 8B are schematic circuit diagrams of the step-down unit of the third embodiment.

### DETAILED DESCRIPTION

According to one embodiment, a semiconductor memory device includes a substrate of a first conductivity type; a memory cell unit provided on the substrate and including a plurality of memory cells; a bit line being electrically connected to the memory cells; a first semiconductor area of a second conductivity type provided on the substrate; a second semiconductor area of the first conductivity type provided on the first semiconductor area; a first transistor provided on the second semiconductor area; a second transistor provided on the substrate; and a control unit. The first transistor includes a first gate electrode, a first gate insulating film, a first electrode and a second electrode. the second electrode is electrically connected to the bit line. The second transistor includes a second gate electrode, a second gate insulating film thicker than the first gate insulating film, a third electrode and a fourth electrode. The fourth electrode is electrically connected to the first electrode. The control unit is configured to be able to performing an erase operation, the erase operation including: applying a first voltage to the first semiconductor area and the bit line; applying a second voltage to the second semiconductor area, the second voltage being equal to or lower than the first voltage; and applying a third voltage to the first gate electrode, the third voltage being equal to or lower than the first voltage.

Referring now to drawings, embodiments will be described below. In the drawings, the same elements are denoted by the same reference numerals throughout. In the following embodiments, a description will be given with a p-type as a first conductivity type and an n-type as a second conductivity type. However, the description may be made with the n-type as the first conductivity type and the p-type as the second conductivity type.

### First Embodiment

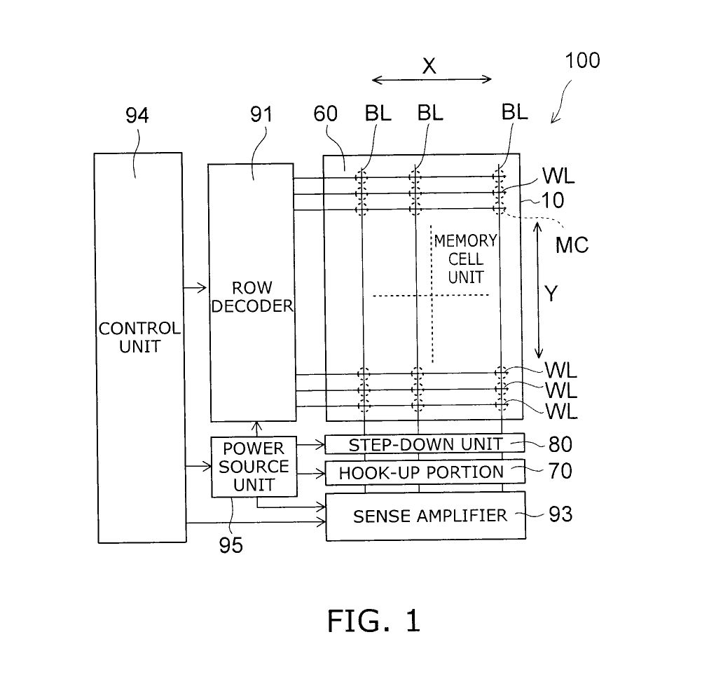

With reference to FIG. 1, an entire configuration of a semiconductor device 100 of an embodiment will be described.

FIG. 1 is a block diagram illustrating a configuration of the semiconductor device 100 of the embodiment will be described.

As shown in FIG. 1, the semiconductor device 100 of the embodiment includes a memory cell unit 60, a power source unit 95, a control unit 94, a sense amplifier 93, a hook-up portion 70 (bit line hook up), a step-down unit 80, and a row decoder 91.

The control unit 94 controls an operation of the semiconductor device 100. For example, the control unit 94 performs a writing operation, an erasing operation, and a reading operation of data with respect to the memory cell unit 60 via the sense amplifier 93 and the row decoder 91.

The power source unit 95 outputs voltages to each part respectively on the basis of signals from the control unit 94. For example, the power source unit 95 supplies a voltage pulse or a current pulse to the hook-up portion 70, the sense amplifier 93, the row decoder 91, and the step-down unit 80 at predetermined timing for the writing, erasing and reading operations.

The sense amplifier 93 is electrically connected to bit lines BL of the memory cell unit 60 via the hook-up portion 70 and the step-down unit 80. The row decoder 91 is electrically connected to an electrode layer WL of the memory cell unit 60.

The sense amplifier 93 amplifies a current read from memory cells MC in the reading operation, and transfers the data to the memory cells MC in the writing operation. The row decoder 91 controls voltages of word lines classified by fixed blocks.

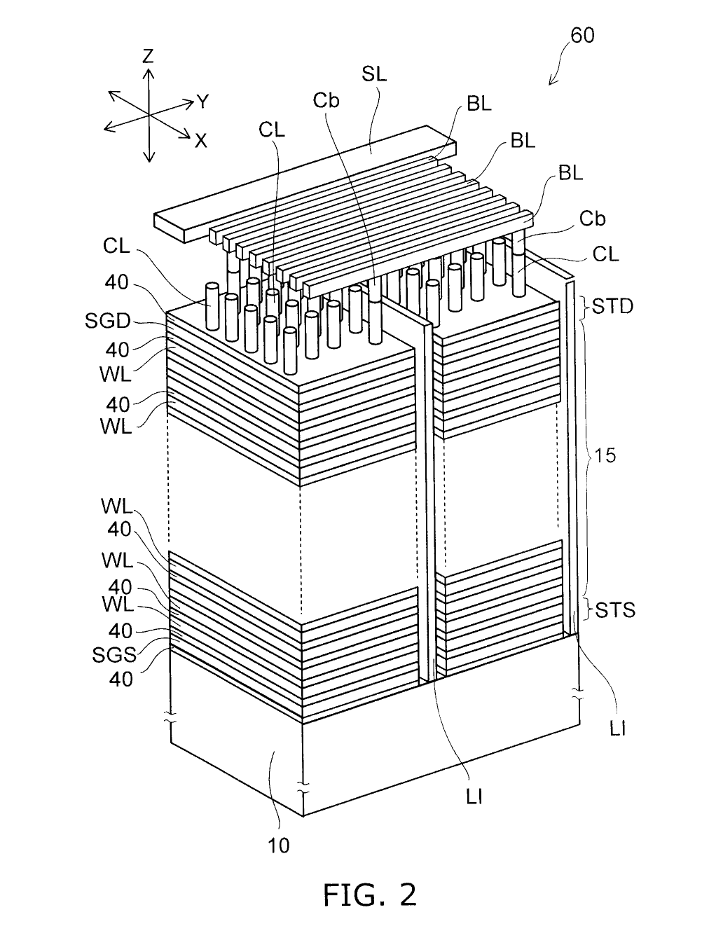

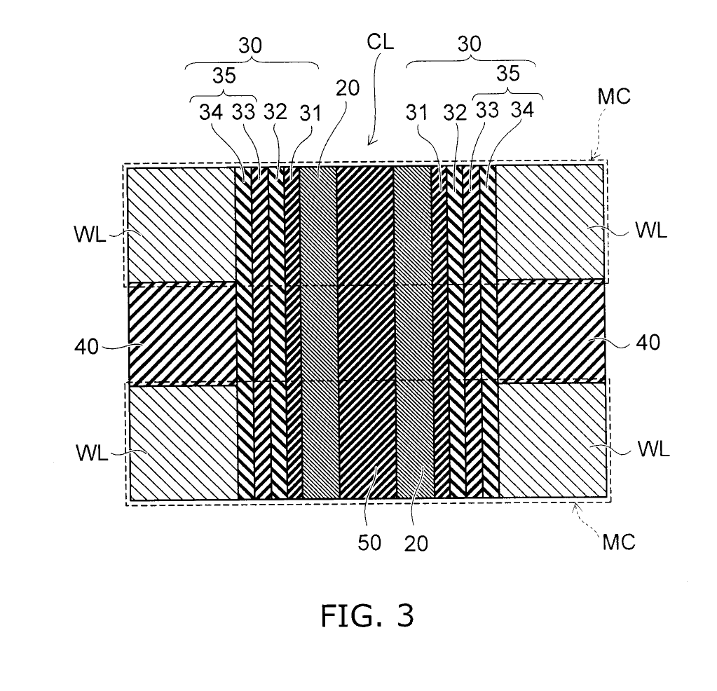

With reference to FIG. 2 and FIG. 3, a configuration of the memory cell unit 60 of the embodiment will be described.

FIG. 2 is a schematic perspective view of the memory cell unit 60 of the embodiment. In FIG. 2, illustration of part of an insulating layer is omitted for better understanding of the drawing.

In FIG. 2, two directions parallel to a main surface of a substrate 10 and orthogonal to each other are defined as an X-direction and a Y-direction, and a direction orthogonal to both of the X-direction and the Y-direction is defined as a Z direction (stacking direction).

The memory cell unit 60 includes the substrate 10, a stacked body 15 provided on the main surface of the substrate 10, a plurality of columnar portions CL, conducting members LI, and an upper layer interconnection provided on the stacked body 15. FIG. 2 illustrates the bit lines BL and a source layer SL as the upper layer interconnection.

The columnar portions CL are formed into a column shape or an elliptic column shape extending in a stacking direction (Z-direction) in the stacked body 15. The conducting members LI extend in the stacking direction (Z direction) of the stacked body 15 and in the X-direction between the upper layer interconnection and the substrate 10, and separate the stacked body 15 in the Y-direction.

The plurality of columnar portions CL is provided, for example, in a hound's-tooth check pattern. Alternatively, the plurality of columnar portions CL may be provided in a square grid shape along the X-direction and the Y-direction.

A plurality of the bit lines BL (for example, a metallic film) are provided on the stacked body 15. The plurality of bit lines BL are separated from each other in the X-direction and the respective bit lines BL extend in the Y-direction. The bit lines BL are electrically connected to the step-down unit 80, which is shown in FIG. 1.

Upper end portions of the columnar portions CL are connected to the bit lines BL via contact portions Cb. The plurality of columnar portions CL selected one each from areas separated by the conducting members LI in the Y-direction are connected to one common bit line BL.

The stacked body 15 includes the plurality of electrode layers WL and a plurality of insulating layers 40. The plurality of electrode layers WL are stacked apart from each other and the plurality of insulating layers 40 are provided between the plurality of electrode layers WL.

Each of the plurality of electrode layers WL and each of the plurality of insulating layers 40 are stacked, for example, alternately. The number of the layers of the shown electrode layers WL is an example only, and the number of layers of the electrode layers WL is arbitrary.

A source-side select gate SGS is provided at a lowermost layer of the stacked body. A drain-side select gate SGD is provided at an uppermost layer of the stacked body 15.

The source-side select gate SGS, the drain-side select gate SGD, and the electrode layers WL include a metal, for example. The source-side select gate SGS, the drain-side select gate SGD, and the electrode layers WL are, for example, silicon layers containing silicon as main components, and for example, boron as an impurity for providing conductivity is doped to the silicon layer. The source-side select gate SGS, the drain-side select gate SGD, and the electrode layers WL may contain metal silicide.

An insulating film mainly containing silicone oxide, for example, is used as the insulating layers 40. The insulating layers 40 may include, for example, a cavity (air gap).

A plurality of the drain-side select gate SGD, and a plurality of the source-side select gate SGS may be provided. The thickness of the drain-side select gate SGD and the thickness of the source-side select gate SGS may be different from that of the single electrode layers WL. The term “thickness” used here represents the thickness in the stacking direction (Z direction) of the stacked body 15.

The conducting members LI are metallic members containing, for example, tungsten, as a main component. Upper end portions of the conducting members LI are connected to the source layer SL provided on the stacked body 15. Lower ends of the conducting members LI are in contact with the substrate 10.

The columnar portions CL each have a semiconductor film 20 (semiconductor pillar portion) as a semiconductor channel. A memory film 30 is provided between the stacked body 15 and the semiconductor film 20. The semiconductor film 20 is, for example, a silicon film containing silicon as a main component. Upper ends of the semiconductor films 20 are electrically connected to the bit lines BL via the contact portions Cb, and lower ends of the semiconductor films 20 are in contact with the substrate 10. The substrate 10 is, for example, a silicon substrate containing an impurity doped therein and hence having conductivity. Therefore, the lower ends of the semiconductor films 20 are electrically connected to the source layer SL via the substrate 10 and the conducting members LI.

The upper end portions of the columnar portions CL are provided with a drain-side select transistor STD, and the lower end portions thereof are provided with a source-side select transistor STS.

The memory cells MC, the drain-side select transistor STD, and the source-side select transistor STS correspond to a vertical-type transistor in which a current flows in the stacking direction (Z direction) of the stacked body 15.

The drain-side select gate SGD functions as a gate electrode (control gate) of the drain-side select transistor STD. An insulating film which functions as a gate insulating film of the drain-side select transistor STD is provided between the drain-side select gate SGD and the semiconductor film 20.

The source-side select gate SGS functions as a gate electrode (control gate) of the source-side select transistor STS. An insulating film which functions as a gate insulating film of the source-side select transistor STS is provided between the source-side select gate SGS and the semiconductor films 20.

A plurality of the memory cells MC using each of the electrode layers WL as a control gate are provided between the drain-side select transistor STD and the source-side select transistor STS.

The plurality of memory cells MC, the drain-side select transistor STD, and the source-side select transistor STS are connected in series via the semiconductor film 20 to constitute a single memory string. The memory strings are provided, for example, a hound's-tooth check pattern in a direction of a plane parallel to an X-Y plane, and the plurality of memory cells MC are provided three-dimensionally in the X-direction, the Y-direction, and the Z direction.

The memory cell unit 60 described above allows erasing and writing of data electrically freely, and is capable of retaining memorized contents even the power is turned OFF.

FIG. 3 is a schematic cross-sectional view illustrating part of the columnar portions CL of the embodiment in an enlarged pattern. An example of the memory cell MC of the embodiment will be described with reference to FIG. 3.

The memory cell MC is, for example, a charge trap type and includes the electrode layers WL, the memory film 30, the semiconductor film 20, and a core insulating film 50.

The memory film 30 and the semiconductor film 20 are provided between the electrode layer WL and the core insulating film 50. The semiconductor film 20 may have, for example, a column shape, and the core insulating film 50 is not provided inside the semiconductor film 20.

The semiconductor film 20 functions as a channel in the memory cell MC, and the electrode layer WL functions as a control gate of the memory cell MC. A charge storage film 32 functions as a data memory layer that stores charge injected from the semiconductor film 20. In other words, the memory cell MC having a structure in which the channel is surrounded by the control gate in the periphery thereof is formed at a portion where the semiconductor film 20 and each of the electrode layers WL intersect.

The memory film 30 includes, from the inside, a block insulating film 35, the charge storage film 32, and a tunnel insulating film 31.

The block insulating film 35 prevents the charge stored in the charge storage film 32 from being diffused to the electrode layers WL. The block insulating film 35 includes, from the inside, a block film 33 and a cap film 34. The block film 33 is, for example, a silicon dioxide film.

As the cap film 34, a film having a dielectric constant higher than that of the block film 33 is used. The cap film 34 includes, for example, at least any of a silicon nitride film and aluminum oxide. The cap film 34 is provided in contact with the electrode layers WL, so that a back tunnel electron injected from the electrode layers WL at the time of erasing may be suppressed.

The charge storage film 32 includes a number of trap sites that catch the charge, which is, for example, a silicon nitride film.

The tunnel insulating film 31 becomes a potential barrier when the charge is injected from the semiconductor film 20 into the charge storage film 32, or when the charge stored in the charge storage film 32 diffuses to the semiconductor film 20. The tunnel insulating film 31 is, for example, a silicon dioxide film.

As the tunnel insulating film 31, a film stack (ONO film) having a structure in which a silicon nitride film is interposed between a pair of silicon dioxide films may be used.

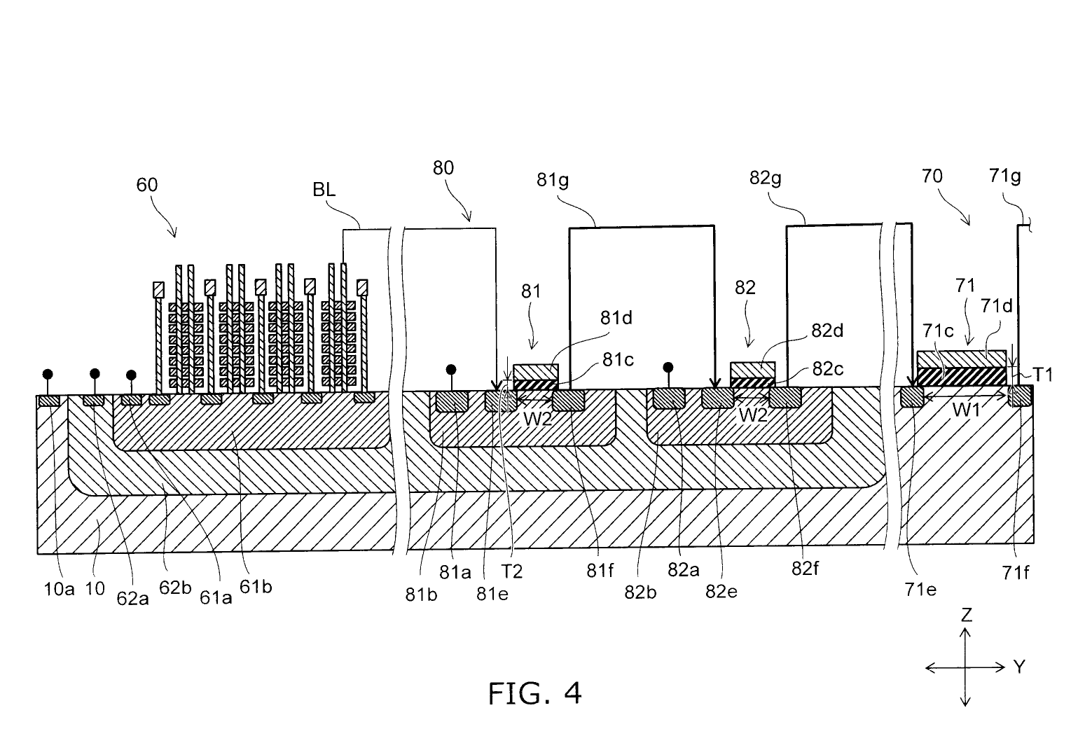

With reference to FIG. 4, a configuration of a periphery of the step-down unit 80 of the embodiment will be described.

FIG. 4 is a schematic cross-sectional view of the memory cell unit 60, the step-down unit 80, and the hook-up portion 70 of the embodiment.

As shown in FIG. 4, the memory cell unit 60, the step-down unit 80, and the hook-up portion 70 are provided on the substrate 10. The substrate 10 is a p-type (first conductivity type) semiconductor substrate, for example. The substrate 10 is electrically connected to the power source unit 95 via an electrode 10a. An n-type (second conductivity type) well area 62b is provided on the substrate 10.

The electrode 10a includes, for example, a contact, and a p-type impurity layer formed on the substrate 10.

The n-type well area 62b is provided integrally with at least part of the memory cell unit 60 and at least part of the step-down unit 80. The n-type well area 62b is electrically connected to the power source unit 95 via an electrode 62a. The electrode 62a, p-type well areas 81b and 82b, and a p-type cell area 61b are provided on the n-type well area 62b.

The electrode 62a includes, for example, a contact, and an n-type impurity layer formed on the n-type well area 62b.

The p-type well areas 81b (second semiconductor area) and 82b (third semiconductor area) are provided in the step-down unit 80. The p-type well areas 81b and 82b are provided with the n-type well area 62b interposed therebetween. In other words, the p-type well areas 81b and 82b are provided as separate well areas. The p-type well areas 81b and 82b are electrically connected to the power source unit 95 via electrodes 81a and 82a.

The memory cell unit 60 includes the bit lines BL. The bit line BL is electrically connected to an impurity area (source or train electrode) 81e of a low-voltage transistor 81 provided in the step-down unit 80.

The step-down unit 80 includes the first low-voltage transistor 81 (first transistor) and a second low-voltage transistor 82 (third transistor).

The first low-voltage transistor 81 is provided on the p-type well area 81b. The first low-voltage transistor 81 includes a gate insulating film 81c (first insulating film), a gate electrode 81d (first gate electrode), impurity areas 81e (second electrode) and 81f (first electrode).

The gate insulating film 81c is provided on the p-type well area 81b. The gate electrode 81d is provided on the gate insulating film 81c, and is electrically connected to the power source unit 95. The impurity areas 81e and 81f are provided within the p-type well area 81b with the gate insulating film 81c interposed therebetween.

The impurity area 81e is electrically connected to the bit line BL. The impurity area 81f is electrically connected to an impurity area 82e of the second low-voltage transistor 82 via an interconnection 81g.

The second low-voltage transistor 82 is provided on the p-type well area 82b. The second low-voltage transistor 82 includes a gate insulating film 82c (third insulating film), a gate electrode 82d (third gate electrode), impurity areas 82e (fifth electrode) and 82f (sixth electrode).

The gate insulating film 82c is provided on the p-type well area 82b. The gate electrode 82d is provided on the gate insulating film 82c, and is electrically connected to the power source unit 95. The impurity areas 82e and 82f are provided within the p-type well area 82b with the gate insulating film 82c interposed therebetween.

The impurity area 82e is electrically connected to the impurity area 81f of the first low-voltage transistor 81. The impurity area 82f is electrically connected to an impurity area 71e of the high-voltage transistor 71 of the hook-up portion 70 via the interconnection 82g.

The gate insulating films 81c and 82c are provided on the p-type well areas 81b and 82b. The gate electrodes 81d and 82d are provided on the gate insulating films 81c and 82c, and are electrically connected to the power source unit 95. The impurity areas 81e, 81f, 82e, and 82f are provided within the p-type well areas 81b and 82b with the gate insulating films 81c and 81d interposed therebetween.

The hook-up portion 70 includes the high-voltage transistor 71 (second transistor). The high-voltage transistor 71 includes a gate insulating film 71c (second insulating film), a gate electrode 71d (second gate electrode), impurity areas 71e (fourth electrode) and 71f (third electrode).

The gate insulating film 71c is provided on the substrate 10. The gate electrode 71d is provided on the gate insulating film 71c and is electrically connected to the power source unit 95. The impurity areas 71e and 71f are provided within the substrate 10 with the gate insulating film 71c interposed therebetween. The impurity area 71e is electrically connected to the impurity area 82f via the interconnection 82g. The impurity area 71f is electrically connected to the sense amplifier 93 via the interconnection 71g.

A thickness T1 of the gate insulating film 71c of the high-voltage transistor 71 is thicker than a thickness T2 of the gate insulating film 81c of the low-voltage transistor 81. The thickness T1 of the gate insulating film 71c of the high-voltage transistor 71 is, for example, not less than 30 nm and not more than 50 nm, and the thickness T2 of the gate insulating film 81c of the low-voltage transistor 81 is, for example, not less than 5 nm and not more than 10 nm.

In the Y-direction, a width W1 between the impurity areas 71e and 71f of the high-voltage transistor 71 is longer than a width W2 between the impurity areas 81e, 81f, 82e, and 82f of the low-voltage transistors 81 and 82.

As the viewed in the Z-direction, an area of the high-voltage transistor 71 overlapping the substrate 10 is larger than each of areas of the low-voltage transistors 81 and 82 overlapping the substrate 10.

If the relationships of connection described thus far are summarized, the impurity area 81e is electrically connected to the memory cell unit 60 via the bit line BL. The impurity area 81f is electrically connected to the impurity area 82e of the low-voltage transistor 82 via the interconnection 81g. The impurity area 82f is electrically connected to the impurity area 71e of the high-voltage transistor 71 via the interconnection 82g. The numbers of the p-type well area, the low-voltage transistor, and the high-voltage transistor are arbitrary.

The p-type cell area 61b (four semiconductor area) is provided on the n-type well area 62b, the p-type cell area 61b is separated from the p-type well areas 81b and 82b. The n-type well area 62b is provided between the p-type cell area 61b and the p-type well area 81b, and between the p-type well area 81b and the p-type well area 82b. An electrode 61a and the memory cell unit 60 are electrically connected to the power source unit 95, the electrode 61a and the memory cell unit 60 are provided on the p-type cell area 61b.

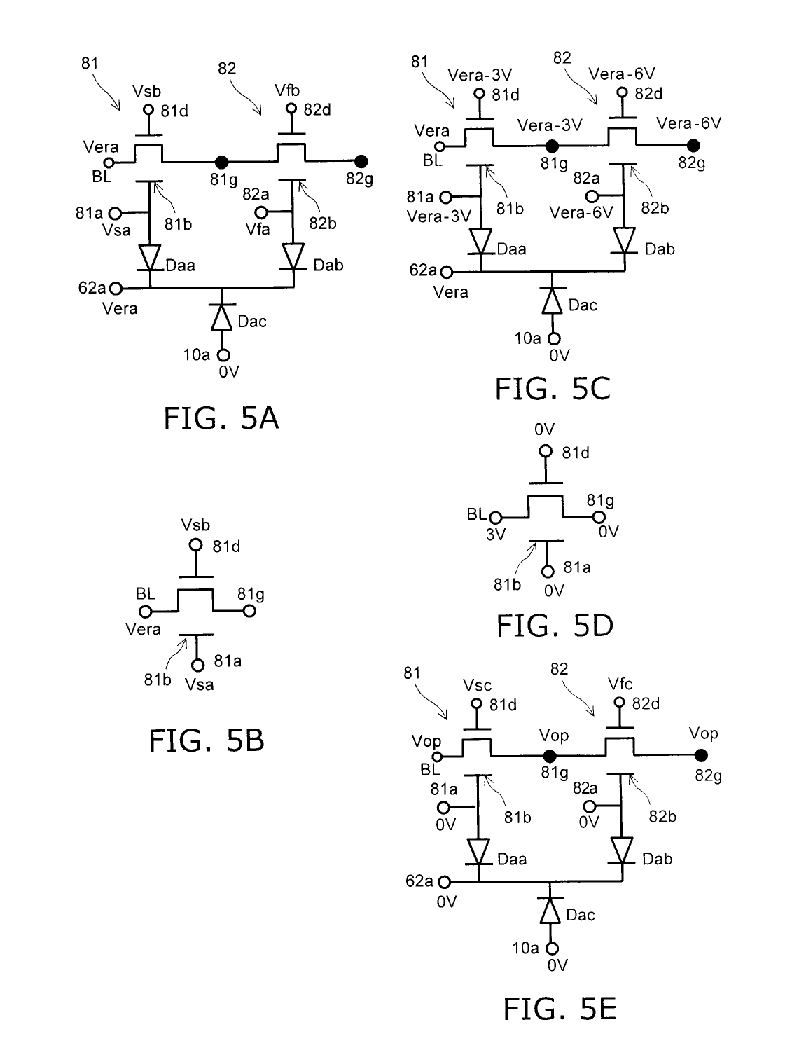

Referring now to FIG. 4 to FIG. 5E, a method of operating the step-down unit 80 will be described.

FIG. 5A to FIG. 5E are schematic circuit diagrams of the step-down unit 80 of the embodiment. Portions between the substrate 10 and the n-type well area 62b, and between the n-type well area 62b and the p-type well area 81b are imitating diodes Daa, Dab, and Dac having the substrate 10 and the p-type well area 81b as anodes, and the n-type well area 62b as a cathode.

Referring to FIG. 5A and FIG. 5B, an erase operation (first operation) will be described.

As shown in FIG. 5A and FIG. 5B, an erase voltage Vera (first voltage) is applied to the bit line BL via the memory cells MC. An erase voltage Vera is also applied to the electrode 62a and the electrode 61a.

A Vsa (second voltage) is applied to the electrode 81a. A Vsb (third voltage) is applied to the gate electrode 81d. The voltage Vsa and Vsb are equal to or lower than the erase voltage Vera. The voltage Vsb may be the same as the voltage Vsa, for example.

A Vfa (fourth voltage) is applied to the electrode 82a. A Vfb (fifth voltage) is applied to the gate electrode 82d. The voltage Vfa is equal to or lower than the voltage Vsa. The Vfb is equal to or lower than the voltage Vfa. The voltage Vfb may be the same as the voltage Vfa, for example.

The voltages Vsb and Vfb are arbitrary as long as the low-voltage transistors 81 and 82 maintain an OFF state.

For example, the voltage applied to the electrode 10a is expressed as a voltage V(10a). At this time, the relationship between voltages is described as the following inequality expression (1) and (2).

V(62a)≧Vsa≧Vsb≧V(10a) (1)

V(62a)Vsa≧Vfa≧Vfb≧V(10a) (2)

FIG. 5C and FIG. 5D illustrate an example of the operation of the step-down unit 80 at the time of erasing from the above-described memory cell MC.

A voltage applied to the low-voltage transistors 81 and 82 will be described.

As illustrated in FIG. 5C, for example, the voltage Vera is applied to the bit line BL. A voltage Vera-3 V is applied to the electrode 81a. A voltage Vera-3 V is applied to the gate electrode 81d. Accordingly, a voltage Vera-3V is applied to the interconnection 81g. The voltage applied to the interconnection 81g is lower than the voltage applied to the bit line BL. A voltage Vera-6 V is applied to the electrode 81a. A voltage Vera-6 V is applied to the gate electrode 82d as the voltage Vfb.

Accordingly, a voltage Vera-6 V is applied to the interconnection 82g. The voltage applied to the interconnection 82g is lower than the voltage applied to the interconnection 81g. In other words, a voltage Vera-6 V is applied to the hook-up portion 70, the voltage Vera-6 V is lower than the voltage Vera applied to the bit line BL.

If the relationship between voltages V (10a) to V (82d) applied to the electrodes 10a to 82d described above is expressed by inequality expression, the following expressions (3) is satisfied.

V(62a)≧V(81a)=V(81d)≧V(82a)=V(82d)≧V(10a) (3)

At this time, the voltage Vera applied to the n-type well area 62b is 3 V higher than the voltage Vera-3 V applied to the p-type well area 81b. In other words, the diode Daa between the n-type well area 62b and the p-type well area 81b is in the reversely biased state.

The voltage Vera applied to the n-type well area 62b is 6 V higher than the voltage Vera-6 V applied to the p-type well area 82b. In other words, the diode Dab between the n-type well area 62b and the p-type well area 82b is in the reversely biased state.

The voltage Vera applied to the n-type well area 62b is higher than 0 V, which is the voltage of the substrate 10. In other words, the diode Dac between the n-type well area 62b and the substrate 10 is in the reversely biased state.

As illustrated in FIG. 5D, when the voltages as described above are applied, the voltage applied to the low-voltage transistor 81 is a differential voltage between the voltage Vera-3 V applied to the p-type well area 81b and the voltage Vera applied to the bit line BL. In other words, practically, a voltage of 3 V is applied to the source electrode of the low-voltage transistor 81, and the potentials of the gate electrode, the drain electrode, and the well become 0 V. In other words, the cut off is also possible at the low-voltage transistor. The voltage applied to the low-voltage transistor 82 is also the same as the voltage applied to the low-voltage transistor 81. In other words, the low-voltage transistor 82 is cut off.

In other words, low-voltage transistors 81 and 82 are used as in the step down unit 80. The low-voltage transistors 81 and 82 have the areas being smaller than the area of the high-voltage transistor. Each of low-voltage transistors 81 and 82 are provided on each of p-type well areas 81b and 82b. Each of voltages applied to the p-type well areas 81b and 82b are equal or lower than each of voltages applied to the low-voltage transistors 81 and 82. Thus, the voltage applied to the step down unit 80 can be practically decreased regardless of a high voltage applied to the bit line BL. The step-down unit 80 applies a voltage lower than the voltage applied to the memory cell unit 60 to the hook-up portion 70.

Referring to FIG. 5E, an operation of the step-down unit 80 at the time of writing in the memory cell MC will be described.

At the time of writing in the memory cell MC, for example, a voltage Vss (0 V, for example) is applied to the memory cell unit 60 in the case of the charge being injected into the charge storage film 32 to raise a threshold value. For example, any voltage Vop of a voltage Vdd is applied to the memory cell unit 60 in the case of the charge not being injected into the charge storage film 32 to raise a threshold value, the voltage Vdd is higher than the voltage Vss. For example, a voltage of 0 V is applied to the electrode 10a, the electrode 62a and the electrode 61a.

A voltage of 0 V is applied to the electrode 81a. For example, a voltage Vsc is applied to the gate electrode 81d, the voltage Vsc is higher than the voltage Vop.

For example, a voltage of 0 V is applied to the electrode 82a. A voltage Vfc is applied to the gate electrode 82d, the voltage Vfc is higher than the voltage Vop.

FIG. 5 E illustrates an example of the operation of the step-down unit 80 at the time of writing in the above-described memory cell MC.

A voltage applied to the low-voltage transistors 81 and 82 will be described.

For example, a voltage Vop is applied to the memory cell unit 60. For example, a voltage of 0 V is applied to the electrode 81a. The voltage Vsc is applied to the gate electrode 81d. Accordingly, the voltage Vop is applied to the interconnection 81g.

For example, a voltage of 0 V is applied to the electrode 82a. The voltage Vfc is applied to the gate electrode 82d. Accordingly, Vop is applied to the interconnection 82g. In other words, the voltage Vop applied to the hook-up portion 70 is equal to the voltage applied to the bit line BL.

Since the operation of the step-down unit 80 at the time of reading out from the memory cell MC is the same as the operation of the step-down unit 80 at the time of writing described above, description will be omitted.

The voltages applied to the gate electrodes 81d and 82d are arbitrary as long as the low-voltage transistors 81 and 82 maintain an ON state.

Subsequently, advantageous effects of the embodiment will be described.

According to the embodiment, the hook-up portion 70 is electrically connected to the memory cell unit 60 via the step-down unit 80. In the step-down unit 80, the low-voltage transistors 81 and 82 are provided on the p-type well areas 81b and 82b. Therefore, the width of the hook-up portion 70 can be reduced; and a size of the device may be reduced. Furthermore, the voltage stress applied to the hook-up portion 70 may be suppressed.

In a semiconductor memory device, increasing a size of the device and applying the voltage stress to the transistor can be a trade-off relation.

For example, as a method of suppressing the voltage stress applied to the high-voltage transistor 71, increasing a distance between the impurity areas 71e and 71f is conceivable. However, this method increases an area of the hook-up portion 70, so that a size of the device becomes larger than the embodiment.

In contrast, according to the embodiment, the low-voltage transistors 81 and 82 are provided in the step-down unit 80, the areas of the low-voltage transistors 81 and 82 are smaller than the area of the high-voltage transistor 71. For example, the width of the hook-up portion 70 can be reduced by approximately 42 um by providing the step-down unit 80. In contrast, the width of the step down unit 80 is approximately 18 um in the Y-direction. Consequently, a width of the device can be reduced by approximately 24 um in the Y-direction. Thus, the low-voltage transistors 81 and 82 are used in the step-down unit 80; and the size of the device may be reduced.

For example, as a method of reducing the size of device, connecting the hook-up portion 70 to the memory cell unit 60 via the bit lines BL only is conceivable. However, the high voltage may be applied to the hook-up portion 70; and a voltage stress may be applied the high-voltage transistor 71 of the hook-up portion 70.

In contrast, according to the embodiment, the low-voltage transistor 81 and 82 are provided in the step-down unit 80, the hook-up portion 70 is electrically connected to the bit lines BL via the step-down unit 80. The voltage applied to the low-voltage transistors 81 and 82 may be decreased by setting the voltage applied to the p-type well areas 81b and 82b. Thus, the voltage applied to the low-voltage transistors 81 and 82 may be reduced stepwise. Accordingly, the voltage applied to the hook-up portion 70 is lower than the voltage applied to the bit line BL. Therefore, the voltage applied to the hook-up portion 70 may be reduced regardless of a high voltage applied to the bit line BL via the memory cell unit 60. Accordingly, the voltage stress applied to the high-voltage transistor 71 may be suppressed. In the configuration described above, the low-voltage transistors 81 and 82 are used in the step-down unit 80; and the size of the device may be reduced simultaneously with suppressing the voltage stress applied to the high-voltage transistor 71.

Examples of the characteristics of the low-voltage transistors 81 and 82 include having better controllability than the high-voltage transistor 71. By using the transistor having a high controllability in the step-down unit 80, flexibility of the voltage applied is improved.

In addition, the p-type well areas 81b and 82b are provided on the n-type well area 62b. The voltage applied to the p-type well areas 81b and 82b is lower than the voltage applied to the n-type well area 62b. In other words, a portion between the n-type well area 62b and the p-type well areas 81b and 82b is in the reversely biased state. Therefore, the p-type well areas 81b and 82b do not have an impact on the substrate 10. In other words, flexibility of the voltage applied to the p-type well areas 81b and 82b is improved, and a reduction of the voltage applied to the hook-up portion 70 is achieved.

### Second Embodiment

In the embodiment, a difference from the above-described embodiment is that the n-type well area 62b is separated between the memory cell unit 60 and the step-down unit 80. Description of the same configurations as those in the above-described embodiment will be omitted.

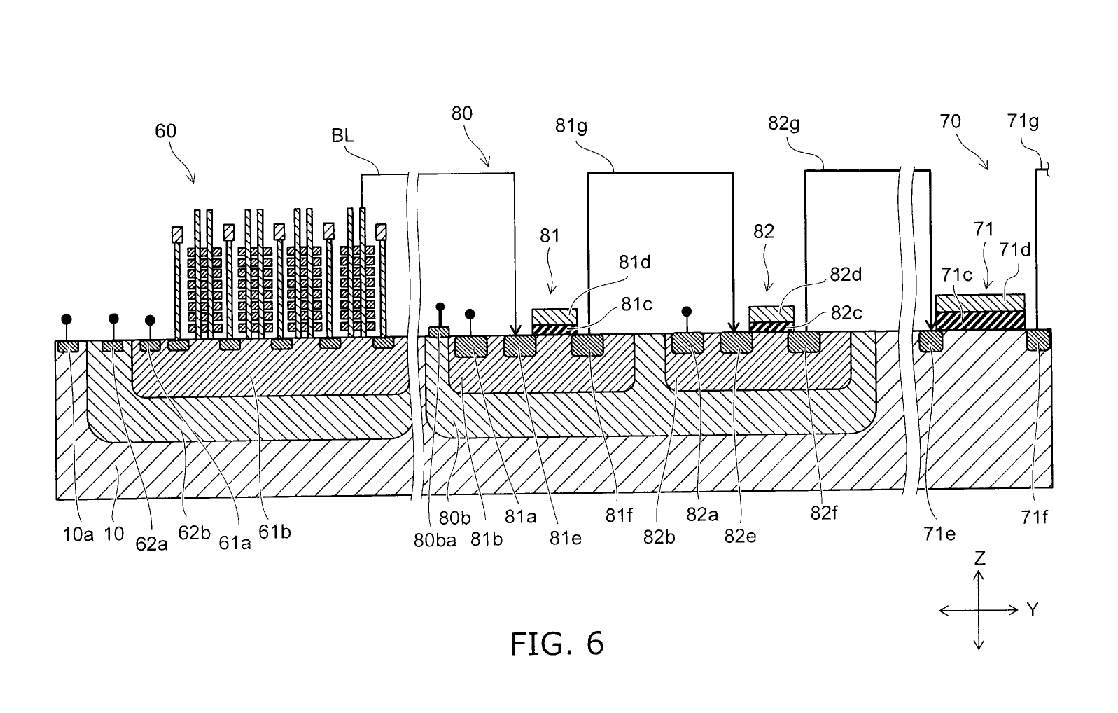

With reference to FIG. 6, a configuration of a periphery of a step-down unit 80 of the embodiment will be described.

FIG. 6 is a schematic cross-sectional view of the periphery of the step-down unit 80 of a second embodiment.

As illustrated in FIG. 6, n-type well areas 62b and 80b are provided on the substrate 10. The n-type well areas 62b and 80b are separated from each other with the substrate 10 interposed therebetween.

An electrode 80ba is provided on an n-type well area 80b (first semiconductor body). The electrode 80ba is electrically connected to the p-type well areas 81b and 82b and the control unit 94.

An electrode 62a is provided on the n-type well area 62b (second semiconductor body). The electrode 62a is electrically connected to the p-type cell area 61b and the control unit 94. An erase operation will be described.

In the embodiment, in addition to the above-described embodiment, different voltages can be applied to the n-type well areas 62b and 80b, respectively. Description of the same operations as those in the above-described embodiment will be omitted.

For example, a voltage Vera is applied to the electrode 62a, and a voltage Vni (a sixth voltage) different from the voltage Vera is applied to the electrode 80ba.

Since the operation of the step-down unit 80 at the time of writing in and reading out from the memory cell MC is the same as the above-described embodiment, description will be omitted.

Subsequently, advantageous effects of the embodiment will be described.

According to the embodiment, in the same manner as the embodiment described above, the hook-up portion 70 is electrically connected to the memory cell unit 60 via the step-down unit 80. In the step-down unit 80, the low-voltage transistors 81 and 82 are provided on the p-type well areas 81b and 82b. Therefore, the low-voltage transistor 81 and 82 are used in the step-down unit 80; and the voltage applied to the hook-up portion 70 may be reduced regardless of the high voltage applied to the bit line BL via the memory cell unit 60. Accordingly, the voltage stress applied to the high-voltage transistor 71 may be suppressed. The low-voltage transistor 81 and 82 are used in the step-down unit 80; and the size of the device may be reduced simultaneously with suppressing the voltage stress applied to the high-voltage transistor 71.

In addition, the p-type well areas 81b and 82b are provided on the n-type well area 80b. The p-type well areas 81b and 82b are separated from the n-type well area 62b, the p-type cell area 61b is provided on the n-type well area 62b. Therefore, flexibility of the voltage applied to the p-type well areas 81b and 82b is improved, and a reduction of the voltage applied to the hook-up portion 70 is achieved.

In addition, according to the embodiment, the n-type well areas 62b and 80b apart from each other are provided. Accordingly, flexibility of the voltage applied to the p-type well areas 81b and 82b is improved, and a further reduction of the voltage applied to the hook-up portion 70 is achieved.

### Third Embodiment

In a third embodiment, the difference from the embodiments described above is that a low-voltage transistor 89 is provided in the hook-up portion 70. Description of the same configurations as those in the above-described embodiment will be omitted.

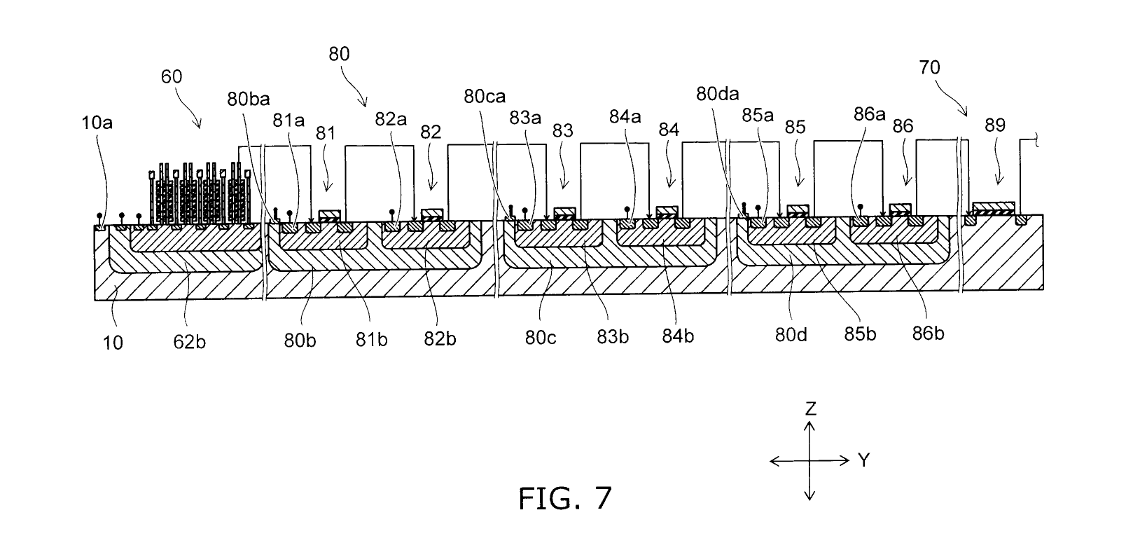

With reference to FIG. 7, a configuration of a periphery of a step-down unit 80 of the embodiment will be described.

FIG. 7 is a schematic cross-sectional view of the periphery of the step-down unit 80 of a third embodiment.

As illustrated in FIG. 7, a plurality of low-voltage transistors 81 to 86 are provided in the step-down unit 80. The plurality of low-voltage transistors 81 to 86 is provided in p-type well areas 81b to 86b apart from each other.

The p-type well areas 81b and 82b are provided on the n-type well area 80b (the first semiconductor portion). The p-type well areas 83b and 84b are provided on the n-type well area 80c (the second semiconductor portion). P-type well areas 85b and 86b are provided on an n-type well area 80d. The n-type well areas 80b to 80d are separated from each other with the substrate 10 interposed therebetween. The plurality of low-voltage transistors 81 to 86 are connected in series to the memory cell unit 60.

The low-voltage transistor 89 is provided on the hook-up portion 70. The low-voltage transistor 89 of the hook-up portion 70 is electrically connected to the memory cell unit 60 via the plurality of low-voltage transistors 81 to 86 of the step-down unit 80.

The number of the plurality of low-voltage transistors of the step-down unit 80 is arbitrary.

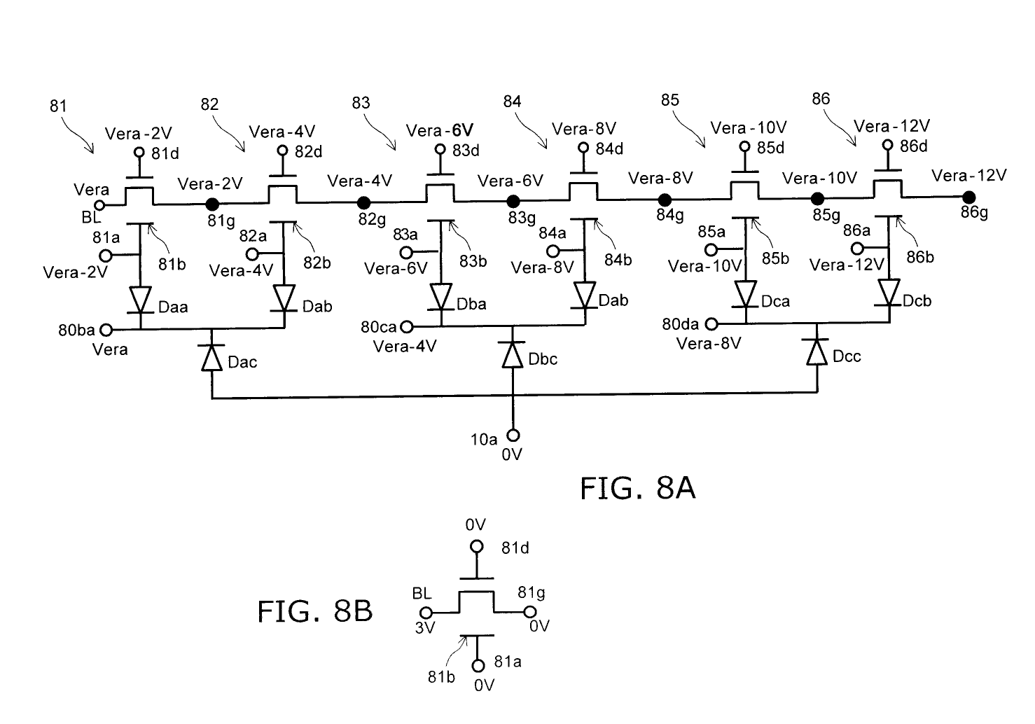

Referring now to FIG. 8A and FIG. 8B, a method of operating the step-down unit 80 will be described.

FIG. 8A and FIG. 8B are circuit drawings of the step-down unit 80 of the embodiment. Portions between the substrate 10 and the n-type well areas 80b to 80d, and between the n-type well areas 80b to 80d and the p-type well areas 81b to 86b are imitating diodes Daa to Dcc having the substrate 10 and the p-type well areas 81b to 86b as anodes, and the n-type well areas 80b to 80d as a cathode.

Since the basic operation of the step-down unit 80 at the time of erasing from the memory cell MC is the same as the embodiment, description will be omitted.

As illustrated in FIG. 8A, for example, the voltage Vera is applied to the bit line BL and the electrode 80ba. A voltage Vera-2 V is applied to the electrode 81a and the gate electrode 81d. Accordingly, a voltage Vera-2 V is applied to the interconnection 81g.

A voltage Vera-4 V is applied to the electrode 82a and the gate electrode 82d. Accordingly, a voltage Vera-4 V is applied to the interconnection 82g.

A voltage Vera-4 V is applied to an electrode 80ca of the n-type well area 80c. A voltage Vera-6 V is applied to the electrode 83a and a gate electrode 83d. Accordingly, a voltage Vera-6 V is applied to the interconnection 83g.

A voltage Vera-8 V is applied to an electrode 84a and a gate electrode 84d. Accordingly, a voltage Vera-8 V is applied to the interconnection 84g.

A voltage Vera-8 V is applied to the electrode 80da of the n-type well area 80d. A voltage Vera-10 V is applied to an electrode 85a and a gate electrode 85d. Accordingly, a voltage Vera-10 V is applied to the interconnection 85g.

A voltage Vera-12 V is applied to an electrode 86a and the gate electrode 86d. Accordingly, a voltage Vera-12 V is applied to the interconnection 86g. In other words, a voltage Vera-12 V is applied to the hook-up portion 70, the voltage Vera-12 V is lower than the voltage Vera applied to the bit line BL.

If the relationship between voltages V (10a) to V (86a) applied to the electrodes 10a to 86a described above is expressed by inequality expression, the following expressions (4) is satisfied.

V(80ba)=V(BL)≧V(81a)=V(81d)≧V(82a)=V(82d)=V(80ca)≧V(83a)=V(83d)≧V(84a)=V(84d)=V(80da)≧V(85a)=V(85d)≧V(86a)=V(86d)≧V(10a) (4)

At this time, the voltage Vera applied to the n-type well area 80b is 2 V higher than the voltage Vera-2 V applied to the p-type well area 81b. In other words, the diode Daa between the n-type well area 80b and the p-type well area 81b is in the reversely biased state.

The voltage Vera applied to the n-type well area 80b is 4 V higher than the voltage Vera-4 V applied to the p-type well area 82b. In other words, the diode Dab between the n-type well area 80b and the p-type well area 82b is in the reversely biased state.

The same applies to diodes Dba, Dbb, Dca, and Dcb between the n-type well areas 80c and 80d and the p-type well areas 83b, 84b, 85b, and 86b.

As illustrated in FIG. 8B, when the voltages as described above are applied, the voltage applied to the low-voltage transistor 81 is a differential voltage between the voltage Vera-2 V applied to the p-type well area 81b and the voltage Vera applied to the bit line BL. In other words, practically, a voltage of 2 V is applied to a source electrode of the low-voltage transistor 81, and the potentials of the gate electrode, the drain electrode, and the well become 0 V. In other words, in the same manner as the embodiments described above, the cut off is also possible at the low-voltage transistor. The voltage applied to the low-voltage transistors 82 to 86 is also the same.

In other words, in the same manner as the embodiments described above, low-voltage transistors 81 to 86 are used as in the step down unit 80, and have the areas being smaller than the area of the high-voltage transistor. The step-down unit 80 applies a voltage lower than the voltage applied to the memory cell unit 60 to the hook-up portion 70. For example, a voltage of a range allowed the usage of the low-voltage transistor is applied to the hook-up portion 70.

Subsequently, advantageous effects of the embodiment will be described.

According to the embodiment, in the same manner as the embodiment described above, the hook-up portion 70 is electrically connected to the memory cell unit 60 via the step-down unit 80. The plurality of low-voltage transistors 81 to 86 is provided in the step-down unit 80. Therefore, the low-voltage transistors 81 to 86 are used in the step-down unit 80; and the voltage applied to the hook-up portion 70 may be reduced regardless of the high voltage applied to the bit line BL via the memory cell unit 60. Accordingly, the voltage stress applied to the low-voltage transistor 89 may be suppressed. The low-voltage transistors 81 to 86 are used in the step-down unit 80; and the size of the device may be reduced simultaneously with suppressing the voltage stress applied to the low-voltage transistor 89.

In addition, the p-type well areas 81b to 86b are provided on the n-type well areas 62b and 80b to 80d. Therefore, flexibility of the voltage applied to the p-type well areas 81b to 86b is improved, and a reduction of the voltage applied to the hook-up portion 70 is achieved.

In the same manner as the embodiments described above, the n-type well areas 62b and 80b to 80d apart from each other are provided. Accordingly, flexibility of the voltage applied to the p-type well areas 81b to 86b is improved, and a further reduction of the voltage applied to the hook-up portion is achieved.

In addition, in the embodiment, the low-voltage transistor 89 is provided on the hook-up portion 70. For example, the voltage resistance of the low-voltage transistor 89 is lower than the voltage resistance of the high-voltage transistor. Therefore, in the case where the low-voltage transistor 89 is used in the hook-up portion 70, easy deterioration may result.

In contrast, in the embodiment, a plurality of low-voltage transistors 81 to 86 is provided in the step-down unit 80. Therefore, the voltage applied to the hook-up portion 70 may be reduced, and deterioration in the low-voltage transistor 89 can be suppressed. Accordingly, the low-voltage transistor 89 is used in the hook-up portion 70; and the size of the device can be reduced significantly in comparison with the case where the high-voltage transistor is used. In other words, the size of the device may be reduced simultaneously with suppressing the voltage stress applied to the low-transistor 89.

According to the embodiments, a configuration of the memory cell unit is arbitrary, and configurations other than the memory cell unit 60 are also applicable. For example, a floating gate type memory cell unit may be employed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate of a first conductivity type;
a memory cell unit provided on the substrate and including a plurality of memory cells;
a bit line being electrically connected to the memory cells;
a first semiconductor area of a second conductivity type provided on the substrate;
a second semiconductor area of the first conductivity type provided on the first semiconductor area;
a first transistor provided on the second semiconductor area, the first transistor including a first gate electrode, a first gate insulating film, a first electrode and a second electrode, the second electrode being electrically connected to the bit line;
a second transistor provided on the substrate and being in direct contact with the substrate, the second transistor including a second gate electrode, a second gate insulating film thicker than the first gate insulating film, a third electrode and a fourth electrode, the fourth electrode being electrically connected to the first electrode; and
a control unit configured to be able to performing an erase operation, the erase operation including:
applying a first voltage to the first semiconductor area and the bit line;
applying a second voltage to the second semiconductor area, the second voltage being equal to or lower than the first voltage; and
applying a third voltage to the first gate electrode, the third voltage being equal to or lower than the first voltage.

2. The device according to claim 1, further comprising:
a third semiconductor area of the first conductivity type provided on the first semiconductor area and provided at a position apart from the second semiconductor area; and
a third transistor provided on the third semiconductor area, the third transistor including a third gate electrode, a second gate insulating film, a fifth electrode and a sixth electrode, the fifth electrode being electrically connected to the first electrode, the sixth electrode being electrically connected to the fourth electrode; wherein
the first electrode and the fourth electrode are electrically connected via the fifth electrode and the sixth electrode,
in the erase operation, the control unit includes:
applying a fourth voltage to the third semiconductor area, the fourth voltage being equal to or lower than the second voltage; and
applying a fifth voltage to the third gate electrode, the fifth voltage being equal to or lower than the fourth voltage.

3. The device according to claim 2, wherein a gate length of the second transistor is longer than a gate length of the first transistor, and is longer than a gate length of the third transistor.

4. The device according to claim 2, wherein
the second voltage is a voltage equal to the third voltage, and
the fourth voltage is a voltage equal to the fifth voltage.

5. The device according to claim 1, wherein the memory cell unit includes:
a stacked body having a plurality of electrode layers separately stacked each other;
a semiconductor film provided in the stacked body, extending in a stacking direction of the plurality of electrode layers, and being electrically connected to the bit line; and
a charge storage film provided between the plurality of electrode layers and the semiconductor film.

6. The device according to claim 5, further comprising:
a fourth semiconductor area of the first conductivity type provided on the first semiconductor area, the fourth semiconductor area separated from the second semiconductor area and the third semiconductor area, wherein
the memory cell unit is provided on the fourth semiconductor area.

7. The device according to claim 6, wherein the control unit includes applying the first voltage to the fourth semiconductor area in the erase operation.

8. The device according to claim 1, wherein the first semiconductor area includes:
a first semiconductor portion, the second semiconductor area provided on the first semiconductor portion; and
a second semiconductor portion separated from the first semiconductor portion.

9. The device according to claim 8, wherein the control unit, in the erase operation, includes:
applying the first voltage to the second semiconductor portion; and
applying a sixth voltage to the first semiconductor, the sixth voltage being different from the first voltage.

10. The device according to claim 8, wherein the memory cell unit is provided on the second semiconductor portion.

11. The device according to claim 2, wherein the first semiconductor area includes:
a first semiconductor portion, the second semiconductor area provided on the first semiconductor portion; and
a second semiconductor portion separated from the first semiconductor portion, the third semiconductor area provided on the second semiconductor portion.

12. The device according to claim 11, wherein the first semiconductor area includes a third semiconductor portion, the third semiconductor portion separated from the first semiconductor portion and the second semiconductor portion, the memory cell unit provided on the third semiconductor portion.

13. A semiconductor memory device comprising:
a substrate of a first conductivity type;
a memory cell unit provided on the substrate and including a plurality of memory cells;
a bit line being electrically connected to the memory cells;
a first semiconductor area of a second conductivity type provided on the substrate;
a second semiconductor area of the first conductivity type provided on the first semiconductor area;
a third semiconductor area of the first conductivity type provided on the first semiconductor area and separated from the first semiconductor portion;
a first transistor provided on the second semiconductor area and including a first gate electrode, a first gate insulating film, a first electrode and a second electrode, the second electrode being electrically connected to the bit line;
a second transistor provided on the substrate and being in direct contact with the substrate, the second transistor including a second gate electrode, a second gate insulating film, a third electrode and a fourth electrode, the fourth electrode being electrically connected to the first electrode; and
a third transistor provided on the third semiconductor area, the third transistor including a third gate electrode, a second gate insulating film, a fifth electrode and a sixth electrode, the fifth electrode being electrically connected to the first electrode, the sixth electrode being electrically connected to the fourth electrode.

14. The device according to claim 13, wherein the second gate insulating film is thicker than the first gate insulating film and thicker than the third gate insulating film.

15. The device according to claim 14, wherein a gate length of the second transistor is longer than a gate length of the first transistor, and is longer than a gate length of the third transistor.

16. The device according to claim 13, wherein a thickness of the second gate insulating film is equal to a thickness of the first gate insulating film, and is equal to a thickness of the third gate insulating film.

17. The device according to claim 13, wherein the memory cell unit includes:
a stacked body including a plurality of electrode layers separately stacked each other;
a semiconductor film provided in the stacked body, electrically connected to the bit line, and extending in the stacking direction of the plurality of electrode layers; and
a charge storage film provided between the plurality of electrode layers and the semiconductor film.

18. The device according to claim 17, further comprising:
a fourth semiconductor area of the first conductivity type provided on the first semiconductor area, the fourth semiconductor area separated from the second semiconductor area and the third semiconductor area, wherein
the memory cell unit is provided on the fourth semiconductor area.

19. The device according to claim 13, wherein the first semiconductor area includes:
the first semiconductor portion, the second semiconductor area provided on the first semiconductor portion; and
the second semiconductor portion separated from the first semiconductor portion.

20. The device according to claim 19, wherein
the third transistor is provided on the second semiconductor portion.
